(19) United States
(12) Patent Application Publication
(10) Pub. No.: US 2007/0056845 A1
(43) Pub. Date: Mar. 15, 2007

(54) Multiple zone sputtering target created through conductive and insulation bonding

(75) Inventors: Yan Ye, Saratoga, CA (US); John M. White, Hayward, CA (US); Akihiro Hosokawa, Cupertino, CA (US); Hien Minh Huu Le, San Jose, CA (US); Elpidio C. Nisperos, San Jose, CA (US); Bradley O. Stimson, San Jose, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/399,122

(22) Filed: Apr. 6, 2006

Related U.S. Application Data
(63) Continuation-in-part of application No. 11/225,922, filed on Sep. 13, 2005.
(63) Continuation-in-part of application No. 11/225,923, filed on Sep. 13, 2005.
(60) Provisional application No. 60/733,939, filed on Nov. 4, 2005.

(51) Int. Cl. C23C 14/32; C23C 14/00

(52) U.S. Cl. 204/192.1; 204/298.12

(57) ABSTRACT

The present invention generally provides a sputtering apparatus and method in which a sputtering target has a plurality of target sections bonded to a common backing plate. Each segment can be bonded to the common backing plate using a different bonding material. One target segment can be bonded to the backing plate using electrically conductive bonding material while another section is bonded to the backing plate using electrically insulating bonding material. Additionally, each different target section can be separately biased.

### CROSS-REFERENCE TO RELATED APPLICATIONS

This application is a continuation in part of U.S. patent application Ser. No. 11/225,922 (APPM/010438) filed Sep. 13, 2005, which is hereby incorporated by reference. The application is a continuation in part of U.S. patent application Ser. No. 11/225,923 (APPM/010438.02) filed Sep. 13, 2005, which is hereby incorporated by reference. This application claims benefit of U.S. Provisional Patent Application Ser. No. 60/733,939 (APPM/010702L), filed Nov. 4, 2005, which is herein incorporated by reference.

### BACKGROUND OF THE INVENTION

1. Field of the Invention

Embodiments of the present invention generally relate to substrate plasma processing apparatuses and methods that are adapted to deposit a film on a surface of a substrate.

2. Description of the Related Art

Physical vapor deposition (PVD) using a magnetron is one method of depositing metal onto a semiconductor integrated circuit to form electrical connections and other structures in an integrated circuit device. During a PVD process a target is electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) magnetron sputtering is the one commercial form of sputtering. The metallic target is biased to a negative DC bias in the range of about −100 to −600 VDC to attract positive ions of the working gas (e.g., argon) toward the target to sputter the metal atoms. Usually, the sides of the sputter chamber are covered with a shield to protect the chamber walls from sputter deposition. The shield is typically electrically grounded and thus provides an anode in opposition to the target cathode to capacitively couple the DC target power to the plasma generated in the sputter chamber.

A magnetron having at least a pair of opposed magnetic poles is typically disposed near the back of the target to generate a magnetic field close to and parallel to the front face of the target. The induced magnetic field from the pair of opposing magnets trap electrons and extend the electron lifetime before they are lost to an anodic surface or recombine with gas atoms in the plasma. Due to the extended lifetime, and the need to maintain charge neutrality in the plasma, additional argon ions are attracted into the region adjacent to the magnetron to form there a high-density plasma. Thereby, the sputtering rate is increased.

PVD is one method of depositing thin films over substrates such as wafer substrates, glass substrates, and other suitable substrates. One problem with current PVD apparatus and methods is uniform deposition as the substrate size increased. Therefore, there is a need for an improved PVD apparatus and method that can form a uniform plasma.

### SUMMARY OF THE INVENTION

The present invention generally provides a plasma processing chamber assembly for depositing a layer on a rectangular large area substrate, comprising a substrate support having a substrate receiving surface that has a central region and an edge region, wherein the substrate receiving surface is in contact with a processing region, a target assembly comprising a backing plate, a first target section having a processing surface that is in contact with the processing region, wherein a first bonding material is provided between the conductive backing plate and first target section that provides electrical communication between the conductive backing plate and first target section, and a second target section having a processing surface that is in contact with the processing region, wherein a second bonding material is provided between the conductive backing plate and second target section so that the conductive backing plate and second target section are electrically isolated from each other, and a power source assembly that is adapted to electrically bias the first target section at a first cathodic bias and the second target section at a second cathodic bias, wherein the first cathodic bias and the second cathodic bias are formed relative to an anodic surface positioned in the processing region.

In a first embodiment of the invention a sputtering target assembly has a plurality of target segments bonded to a single backing plate. At least one target segment is bonded to the backing plate using a first bonding material and at least one other target segment is bonded to the backing plate using a second bonding material. The first bonding material is different from the second bonding material.

In another embodiment of the invention, a method of sputtering a sputtering target assembly is disclosed. The sputtering target assembly has a plurality of target segments bonded to a single backing plate. At least one target segment is bonded to the backing plate using a first bonding material and at least one other target segment is bonded to the backing plate using a second bonding material. The first bonding material is different from the second bonding material. The method involves sputtering material from the plurality of target segments onto a substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C illustrates views of various embodiments of the multizone target assembly that may be used in an exemplary physical vapor deposition chamber.

FIGS. 2-8 illustrates embodiments of the multizone target assembly that may be used in an exemplary physical vapor deposition chamber.

FIG. 9 is a vertical cross-sectional view of an exemplary physical vapor deposition chamber.

### DETAILED DESCRIPTION

The present invention generally provides an apparatus and method for processing a surface of a substrate in a PVD chamber that has a sputtering target that has individually bonded sections to improve the deposition uniformity. In general, aspects of the present invention can be used for flat panel display processing, semiconductor processing, solar cell processing, or any other substrate processing. The invention is illustratively described below in reference to a physical vapor deposition system, for processing large area substrates, such as a PVD system, available from AKT®, a division of APPLIED MATERIALS®, Inc., Santa Clara, Calif. However, it should be understood that the apparatus and method may have utility in other system configurations, including those systems configured to process large area round substrates. An exemplary system in which the present invention can be practiced is described in U.S. patent application Ser. No. 11/225,922, filed Sep. 13, 2005, which is hereby incorporated by reference in its entirety.

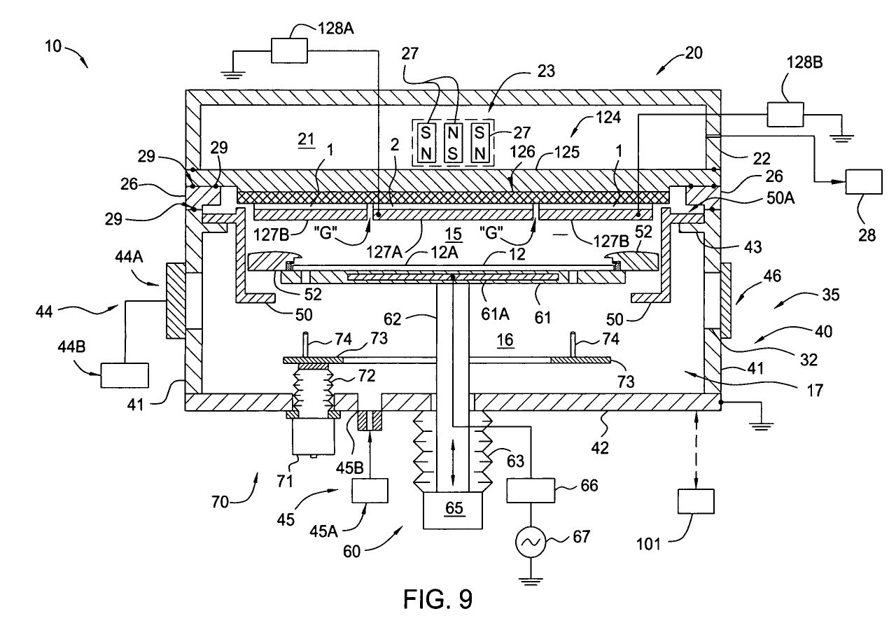

FIG. 9 illustrates a vertical cross-sectional view of one embodiment of a processing chamber 10 that may be used to perform aspects of the invention described herein. The multizone target assembly 124 is used to generate a plasma of varying density in the processing region 15 of the processing chamber 10 by separately biasing different target sections 127A, 127B to achieve a desired sputter deposition profile across the substrate surface. The target sections 127A, 127B are separately bonded to the backing plate 125 using bonding material 1, 2, and are electrically isolated from each other by a separator G. The processing region 15 is the region formed between the multizone target assembly 124, a surface 12A of a substrate 12 positioned on the substrate support 61, and the shield 50.

The processing chamber 10 contains a lid assembly 20 and a lower chamber assembly 35. The lower chamber assembly 35 contains a substrate support assembly 60, chamber body assembly 40, a shield 50, a process gas delivery system 45 and a shadow frame 52. The chamber body assembly 40 contains one or more chamber walls 41 and a chamber base 42. The one or more chamber walls 41, the chamber base 42 and a surface of the multizone target assembly 124 form a vacuum processing area 17 that has a lower vacuum region 16 and a processing region 15. In one aspect, a shield mounting surface 50A of the shield 50 is mounted on or connected to a grounded chamber shield support 43 formed in the chamber walls 41 to ground the shield 50. In one aspect, the process chamber 10 contains a process gas delivery system 45 that has one or more gas sources 45A that are in fluid communication with one or more inlet ports 45B that are used to deliver a process gas to the vacuum processing area 17. In one aspect, the process gas could be delivered to the processing region 15 through the multizone target assembly 124. In one embodiment, the substrate support 61 may contain RF biasable elements 61A embedded within the substrate support 61 that can be used to capacitively RF couple the substrate support 61 to the plasma generated in the processing region 15 by use of an RF power source 67 and RF matching device 66.

The substrate support assembly 60 contains a substrate support 61, a shaft 62 that is adapted to support the substrate support 61, and a bellows 63 that is sealably connected to the shaft 62 and the chamber base 42 to form a moveable vacuum seal that allows the substrate support 61 to be positioned in the lower chamber assembly 35 by the lift mechanism 65.

The lower chamber assembly 35 will also contain a substrate lift assembly 70, slit valve 46 and vacuum pumping system 44. The lift assembly 70 contains three or more lift pins 74, a lift plate 73, a lift actuator 71, and a bellows 72 that is sealably connected to the lift actuator 71 and the chamber base 42 so that the lift pins 74 can remove and replace a substrate positioned on a robot blade (not shown) that has been extended into the lower chamber assembly 35 from a central transfer chamber (not shown). The extended robot blade enters the lower chamber assembly 35 through the access port 32 in the chamber wall 41 and is positioned above the substrate support 61 that is positioned in a transfer position (not shown). The vacuum pumping system 44 (elements 44A and 44B) may contain a cryo-pump, turbo pump, cryo-turbo pump, rough pump, and/or roots blower to evacuate the lower vacuum region 16 and processing region 15 to a desired base and/or processing pressure.

To control the various processing chamber 10 components, power supplies 128A, 128B, gas supplies, and process variables during a deposition process, a controller 101 is used. The controller 101 is a microprocessor-based controller configured to receive inputs from a user and/or various sensors in the plasma processing chamber and appropriately control the plasma processing chamber components in accordance with the various inputs and software instructions retained in the controller's memory.

The lid assembly 20 contains a multizone target assembly 124, a lid enclosure 22, a ceramic insulator 26, one or more o-ring seals 29 and one or more magnetron assemblies 23 that are positioned in a target backside region 21. A vacuum pump 28 is used to evacuate the target backside region 21 to reduce the stress induced in the multizone target assembly 124 due to the pressure differential created between the processing region 15 and the target backside region 21. In one aspect, the ceramic insulator 26 is not required to provide electrical isolation between the backing plate 125 of the multizone target assembly 124 and the chamber body assembly 40. The multizone target assembly 124 generally contains a backing plate 125, an insulator 126, and two or more target sections 127A, 127B. Generally, each magnetron assembly 23 will have at least one magnet 27 that has a pair of opposing magnetic poles (i.e., north (N) and south (S)) that create a magnetic field (B-field) that passes through the multizone target assembly 124 and the processing region 15. FIG. 9 illustrates a vertical cross-section of one embodiment of a processing chamber 10 that has one magnetron assembly 23 that contain three magnets 27, which are positioned in the target backside region 21 at the back of the multizone target assembly 124. An exemplary magnetron assembly, that may be adapted to benefit the invention described herein, is further described in the commonly assigned U.S. patent application Ser. No. 10/863,152, filed Jun. 7th, 2004, which claims the benefit of U.S. Provisional Patent Application Ser. No. 60/534,952, filed Jan. 7th, 2004, and is hereby incorporated by reference in its entirety.

Bonded Target Configuration

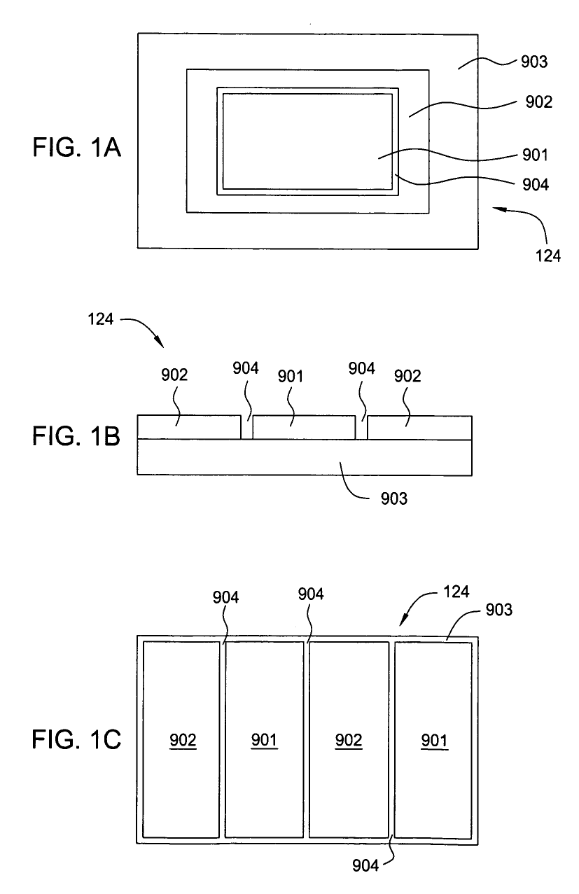

In one embodiment, each of the target sections are bonded directly to a single-piece electrically conductive backing plate using either an electrically conductive bonding material or an electrically insulating bonding material. The FIGS. 1A-1C shown below are examples of some typical multi-piece target configurations. Referring to FIGS. 1A-1C, the first target section 901 and the second target section 902 are both bonded to a backing plate 903, to form a multizone target assembly 124. The target sections are electrically isolated from each other by a separator 904. While reference is made to an electrically conductive backing plate, it is to be understood that the backing plate could also be an electrically insulating backing plate.

It should also be noted that the target sections can all be electrically isolated from each other. For example, an air gap, an insulator barrier, dark space shield, or gas introduction tubes can be provided between the target sections. An exemplary example of electrically insulating the target sections from one another using an insulating barrier or gas introduction tubes is provided in U.S. patent application Ser. No. 11/225,922, filed Sep. 13, 2005 which is incorporated herein by reference.

In one aspect, the target sections are electrically isolated from each other and supported by an insulator. In one aspect, the insulator is made of an electrically insulative material, such as a ceramic material (e.g., aluminum oxide (Al₂O₃), aluminum nitride (AIN), quartz (SiO₂), Zirconia (ZrO)), a polymeric material (e.g., polyimide (Vespel®) or other suitable material that may be able to structurally withstand the temperatures seen by the multizone target assembly 124 during processing. The thickness of the insulator is sized to provide electrical isolation between the target sections and between the target sections and the backing plate. In one aspect, the target sections are brazed or bonded by conventional means to the insulator at a bonded region. In another aspect, the target sections are mechanically fastened (e.g., bolts) to the insulator by conventional means.

In one embodiment, the first target section 901 is bonded with an electrically-conductive material to form an electrical connection between the first target section 901 and the backing plate 903. The second target section 902 of the multizone target assembly 124 is bonded with an electrically-insulating material to the backing plate 903, so that it is not in electrical communication with the backing plate 903. A separate electrical connection (not shown) will be provided between a first power supply (not shown) so that the first power supply can bias the second target section 902 through the electrical connection. The electrical connection may be an electrical plug assembly and insulated electrical power feed, which is embedded inside backing plate 903. A second power supply, or second electrical connection connected to the first power supply, is adapted to separately bias the backing plate 903 and first target section 901 relative to the second target section 902.

In another embodiment, the first target section 901 is bonded with an electrically-insulating material and the second target section 902 is bonded with an electrically-conducive material to the backing plate 903, so that the second target section 902 can be electrically driven with the backing plate 903 and the first target section 901 can be biased separately.

While FIG. 1A shows the target segments as a center target surrounded by an additional target segment, it should be understood that additional arrangements are possible. For example, FIG. 1C shows an arrangement where the target segments are in strips that are adjacent to one another. Additional arrangements for the target segments can be utilized.

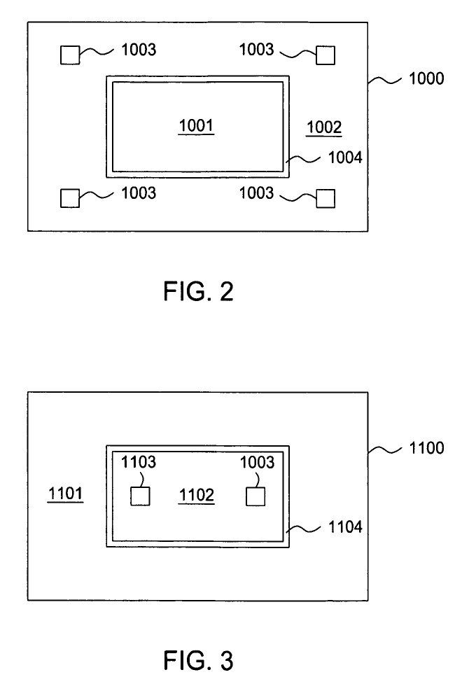

FIG. 2 shows another embodiment. FIG. 2 shows a target 1000 with a conductive bonded target segment 1001 surrounded by an insulatively bonded target segment 1002. The insulatively bonded target segment 1002 has conductive feedthroughs 1003 provided through the bonding material so that power can be directly applied to the target. The target segments are electrically isolated from each other by a separator 1004. While only two target sections have been shown, it is to be understood that additional target segments can be present.

FIG. 3 shows an additional embodiment. FIG. 3 shows a target 1100 having an insulatively bonded target segment 1102 surrounded by a conductively bonded target segment 1101. The insulatively bonded target segment 1102 has conductive feedthroughs 1103 provided through the bonding material so that power can be directly applied to the target. The target segments are electrically isolated from each other by a separator 1104. While only two target sections have been shown, it is to be understood that additional target segments can be present.

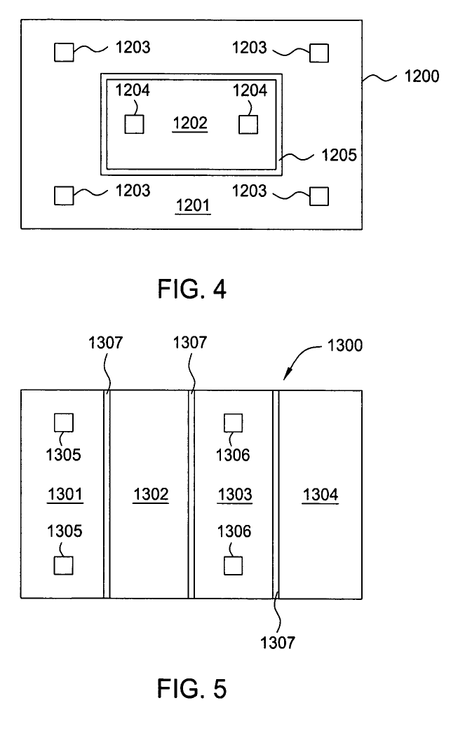

FIG. 4 shows an additional embodiment where all of the target segments are bonded with insulative materials. The target 1200 has a first insulatively bonded target segment 1201 that surrounds a second insulatively bonded target segment 1202. Each segment has conductive feedthroughs 1203, 1204 provided through the bonding material so that power can be directly applied to the target. The bonding material for the first target segment 1201 can be the same as or different from the second target segment 1202. The target segments are electrically isolated from each other by a separator 1205. While only two target sections have been shown, it is to be understood that additional target segments can be present.

Other target arrangements are also possible. For instance, FIG. 5 shows an alternative target arrangement. The target 1300 has several target segments. The first target segment 1301 is bonded with insulative bonding material. The second target segment 1302 is bonded with conductive bonding material. The third target segment 1303 is bonded with insulative material. The fourth target segment 1304 is bonded with conductive bonding material. The insulatively bonded target segment all have conductive feedthroughs 1305, 1306 that are provided through the bonding materials so that power can be applied directly to the target segments. The target segments are electrically isolated from each other by a separator 1307. While only four target sections have been shown, it is to be understood that additional target segments can be present.

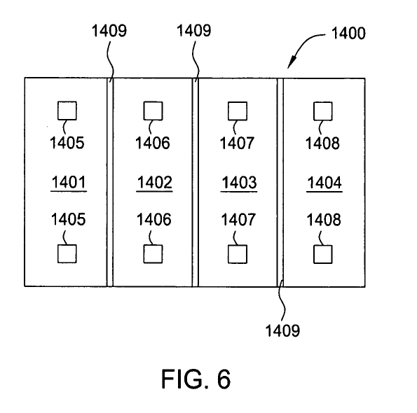

All of the target segments can be bonded with insulative bonding material. FIG. 6 shows an embodiment where the target 1400 has several target segments 1401-1404 that are all insulatively bonded. Each segment has conductive feedthroughs 1405-1408 provided through the bonding material to provide power directly to the target. The target segments are electrically isolated from each other by a separator 1409. While only four target sections have been shown, it is to be understood that additional target segments can be present.

It is important to note that each target segment can be bonded with different bonding material. For instance, when considering the target shown in FIG. 6, each target segment can be bonded to the backing plate using a different bonding material. Additionally, each target segment could be bonded to the backing plate using the same bonding material. For instance, the insulative bonding material for the target shown in FIG. 6 could be the same for each target segment.

By providing different bonding materials for different target segments across a common backing plate, it is possible to control the power provided to each individual segment. By controlling the power to each individual segment, film properties, can be tailored to suit ones needs.

Different power provided to different targets across a common backing plate is beneficial at preventing arcing. For instance, one target segment could be powered as the anode while the adjacent target segment could be powered as the cathode. The current could then be reversed. By alternating the power to the target segments, arcing will be minimized.

Additionally, different power levels can be applied to different target segments to control the amount of material deposited. For instance, if more deposition is desired at an edge of a substrate than at the middle of the substrate, the power applied to a target segment above the edge of the substrate can have more power applied to it than a target segment above the middle of the substrate.

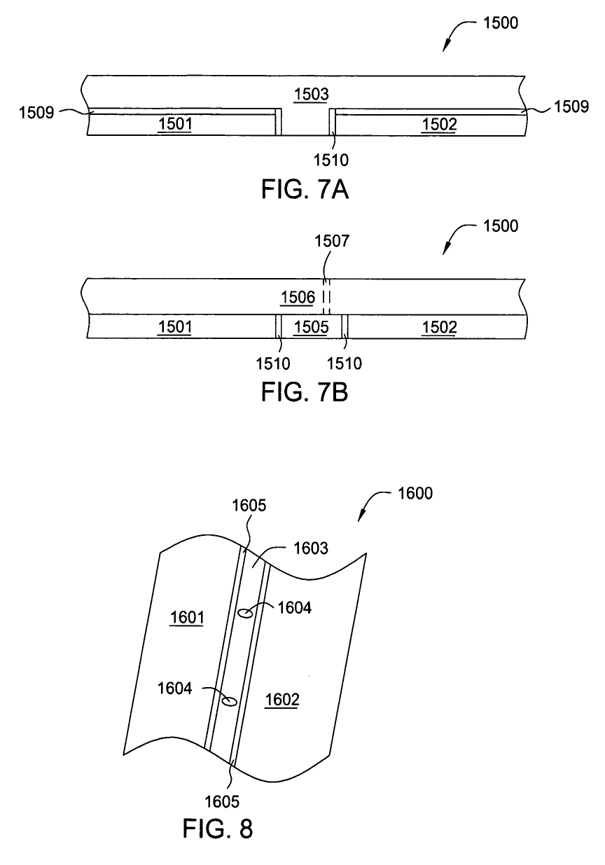

The target segments can be separated by a dark space shield. FIGS. 7A and 7B show a target assembly 1500 in which target segments 1501, 1502 are separated by a dark space shield. FIG. 7A shows the dark space shield and the backing plate integrated into a single dark space shield assembly 1503. The target segments are electrically isolated from the dark space shield by a separator 1510. Each target segment is bonded to the dark space shield assembly 1503 with a bonding layer 1508, 1509 and is provided with conductive feedthroughs (not shown) to power the target segments. FIG. 7B shows a separate dark space shield 1505 bonded to the backing plate 1506. In each case, the dark space shield can be formed of any conductive material suitable for functioning as a dark space shield. Stainless steel is the most preferred material for the dark space shield. While only two target sections have been shown, it is to be understood that additional target segments can be present. A conductive feedthrough 1507 is provided to the dark space shield 1505 to selectively power the dark space shield 1505 as a cathode and an anode.

The dark space shield 1505 can be bonded to the backing plate 1506 using dielectric bonding. The dielectric bonding can be any insulative bonding material. Of particular preference is glass beads dispersed within an elastomer.

The dark space shield can be grounded or biased. The dark space shield will normally function as an anode, but whenever the dark space shield gets coated with sputtering target material, bias can be applied to the dark space shield to sputter the target material from the dark space shield. When the dark space shield is biased, the target segments will function as an anode. Additionally, the dark space shield can be flush with the surface of the target segments or it can be raised above the level of the target segments.

Within the dark space shield, gas introduction tubes can be provided. FIG. 8 shows a target assembly 1600 in which target segments 1601, 1602 are separated by a dark space shield 1603. The dark space shield 1603 and the target segments 1601, 1602 are electrically isolated from each other by a separator 1605. Within the dark space shield, gas inlets 1604 are present. The gas inlets 1604 are beneficial for ensuring that the sputtering gas is evenly distributed within the chamber. While only two target sections have been shown, it is to be understood that additional target segments can be present.

A rippling power supply can be provided to the target segments and adjacent dark space shields. A rippling power supply is where a first target segment is powered to sputter material while all other target segments and dark space shields are grounded to function as an anode. Then, the target segment adjacent to the first target segment is powered while all other target segments and dark space shields are grounded to function as anodes. The altering of supplying power and grounding will continue down a line until all target segments in succession have had power supplied to sputter material. By powering individual, adjacent target segments in succession, a rippling power supply is provided to the target assembly. The rippling power supply will help prevent arcing across the target assembly.

These various embodiments can be applied to many other arrangements of multi-piece targets than those shown in FIG. 1A-6, and thus the figures as shown are not intended to be limiting as to the scope of the invention. These embodiments lend themselves easily to applications of Dual (DC) Magnetrons and AC Magnetrons.

One advantage of these embodiments is that it may provide a simple method of making a multizone target assembly. The multizone target assembly is desirable since it allows the application of different amounts of electrical plasma-generating power to be delivered to different regions of a sputtering target, so that the uniformity of the sputter-deposited film can be optimized. These embodiments have the advantage that they reduce the number of pieces that are required to form the multizone target assembly. Having fewer pieces will make the multizone target assembly less expensive to manufacture than a multi-piece backing plate design and will also reduce the number of mechanical interfaces, which will lead to fewer reliability issues.

While the foregoing is directed to embodiments of the present invention, other and further embodiments of the invention may be devised without departing from the basic scope thereof, and the scope thereof is determined by the claims that follow.

We claim:

1. A sputtering target assembly comprising:
a backing plate;
at least one target segment insulatively bonded to the backing plate; and
at least one target segment conductively bonded to the backing plate.

2. The sputtering target assembly of claim 1, wherein one target segment is a center target segment and each additional target segment surrounds the center target segment.

3. The sputtering target assembly of claim 1, wherein said target segments are arranged in a strip pattern.

4. The sputtering target assembly of claim 1, wherein said target segments are electrically isolated from each other by an air gap or an insulating barrier.

5. The sputtering target assembly of claim 1, further comprising a dark space shield between the target segments.

6. The sputtering target assembly of claim 5, wherein the dark space shield is grounded.

7. The sputtering target assembly of claim 5, wherein the dark space shield is electrically biased as an anode.

8. The sputtering target assembly of claim 1, wherein each target segment is coupled to a different power supply.

9. A sputtering target assembly comprising:
a backing plate;
a plurality of target segments, wherein each target segment is insulatively bonded to the backing plate; and
feedthroughs coupling each target segment to a power source.

10. The sputtering target assembly of claim 9, wherein one target segment is a center target segment and each additional target segment surrounds the center target segment.

11. The sputtering target assembly of claim 9, wherein said target segments are arranged in a strip pattern.

12. The sputtering target assembly of claim 9, wherein said target segments are electrically isolated from each other by an air gap or an insulating barrier.

13. The sputtering target assembly of claim 9, further comprising a dark space shield between the target segments.

14. The sputtering target assembly of claim 13, wherein the dark space shield is grounded.

15. The sputtering target assembly of claim 13, wherein the dark space shield is electrically biased as an anode.

16. The sputtering target assembly of claim 9, wherein each target segment is coupled to a different power supply.

17. A method of sputtering a material, comprising:
providing at least one target segment insulatively bonded to a backing plate;
providing at least one target segment conductively bonded to the backing plate;
coupling separate power sources to the target segments; and
biasing the target segments through the separate power sources to sputter material from the target segments.

18. The method of claim 17, wherein the target segments are arranged in a strip pattern or as a center target segment surrounded by the other target segments.

19. The method of claim 17, further comprising providing a dark space shield between each target segment.

20. The method of claim 19, wherein the dark space shield is electrically isolated from each target segment and electrically grounded.

21. The method of claim 19, wherein the dark space shield is electrically isolated from each target segment and electrically biased as an anode.

22. A method of sputtering a material, comprising:
providing a plurality of target segments insulatively bonded to a backing plate;
coupling separate power sources to the target segments; and
biasing the target segments through the separate power source to sputter material from the target segments.

23. The method of claim 22, wherein the target segments are arranged in a strip pattern or as a center target segment surrounded by the other target segments.

24. The method of claim 22, further comprising a dark space shield between each target segment.

25. The method of claim 24, wherein the dark space shield is electrically isolated from each target segment and electrically grounded.

26. The method of claim 24, wherein the dark space shield is electrically isolated from each target segment and electrically biased as an anode.
